(19) United States
(12) Patent Application Publication
(10) Pub. No.: US 2001/0053168 A1
(43) Pub. Date: Dec. 20, 2001

(54) Asymmetric optical waveguide structure for reducing loss and enhancing power output in semiconductor lasers

(76) Inventor: Atul Mathur, Santa Clara, CA (US)

Correspondence Address: HARNESS, DICKEY & PIERCE, PLC, P.O. BOX 828, BLOOMFIELD HILLS, MI, 48303, US

(21) Appl. No.: 09/851,999

(22) Filed: May 10, 2001

Related U.S. Application Data
(60) Provisional application No. 60/203,750, filed on May 12, 2000.

(51) Int. Cl. H01S 5/00

(52) U.S. Cl. 372/45

(57) ABSTRACT

A semiconductor laser has a waveguide modifying layer to increase output power. Specifically, the laser includes a p-doped cladding layer adjacent to a first side of an active layer. An n-doped cladding layer is positioned on a second side of the active layer. The waveguide modifying layer is disposed between the n-doped cladding layer and the active layer, where the modifying layer reduces an extent by which an optical mode confined by the active layer extends into the p-doped cladding layer.

### CROSS-REFERENCE TO RELATED APPLICATIONS

This application is claims priority to a provisional application, Ser. No. 60/203,750, filed on May 12, 2000.

### BACKGROUND OF THE INVENTION

1. Technical Field

The present invention generally relates to semiconductor lasers. More particularly, the invention relates to a semiconductor laser having a waveguide modifying layer that reduces optical losses and enables higher output power.

2. Discussion

Semiconductor lasers have rapidly been growing in popularity in a number of fields and applications. For example, with the development of wavelength multiplexed optical communications networks that include Raman amplifiers and erbium-doped fiber amplifiers, there is an increasing need for high power semiconductor lasers operating at wavelengths suitable for pumping the fiber amplifiers. In certain amplifiers, the erbium-doped fiber bears the communication signal and is optically pumped with a semiconductor laser having a high-powered continuous output at an optical frequency slightly higher than that of the communication signal. Ideally, a single semiconductor laser can generate hundreds of milliwatts. In fact, when pumping fiber amplifiers, powers reaching above the one watt level are preferred.

The typical semiconductor laser has an active layer containing one or more optical modes, a p-doped cladding layer and an n-doped cladding layer. The p-doped cladding layer is adjacent to a first side of the active layer, while the n-doped cladding layer is adjacent to a second side of the active layer.

The pump wavelength for Raman amplifiers is typically longer than for erbium-doped amplifiers, requiring that the pump laser be based on indium phosphide, rather than gallium arsenide. However, a major loss mechanism in indium phosphide lasers is free carrier absorption in the p-doped cladding layer. The mechanism of free carrier absorption has a strong wavelength dependence, and is particularly strong for the wavelengths typically used for pumping Raman amplifiers.

This loss mechanism has a major impact on the function of a laser device in two different ways. First, the loss affects the length of a cavity, since the loss is constant per unit length. Therefore, as length increases, the losses increase, and increasing cavity length to produce higher powers become less useful. The second type of loss occurs when the vertical confinement of the laser structure is low, since there is greater optical intensity in the cladding layers. Both long cavity and low vertical confinement are desirable characteristics for high power lasers.

Therefore, there is a need to reduce the optical losses resulting from the p-doped cladding layer, in order to improve the operating characteristics of high power semiconductor lasers, particularly those based on indium phosphide.

The above and other objectives are provided by a semiconductor laser in accordance with the principles of the present invention. The semiconductor laser has a p-doped cladding layer adjacent to a first side of an active layer. An n-doped cladding layer is positioned on a second side of the active layer. The laser further includes a waveguide modifying layer disposed between the n-doped cladding layer and the active layer. The modifying layer reduces an extent by which an optical mode confined by the active layer extends into the p-doped cladding layer. The modifying layer therefore reduces optical losses and, as will be discussed in greater detail below, enables higher output power.

Further in accordance with the present invention, a semiconductor laser waveguide modifying layer is provided. The modifying layer has a first surface adjacent to a second side of an active layer of the laser, and a second surface adjacent to a first side of an n-doped cladding layer of the laser. A modifying material forms the surfaces, where the modifying material has a refractive index that is higher than a refractive index of the n-doped cladding layer such that the modifying layer pulls an optical mode away from a p-doped cladding layer of the laser.

In another aspect of the invention, a method for fabricating a semiconductor laser includes the step of coupling a p-doped cladding layer to a first side of an active layer. A waveguide modifying layer is coupled to a second side of the active layer, and an n-doped cladding layer is coupled to the modifying layer. The n-doped cladding layer has a lower index of refraction than the modifying layer such that the modifying layer reduces an extent by which an optical mode confined by the active layer extends into the p-doped cladding layer.

In another embodiment of the invention, a semiconductor laser includes a layered semiconductor structure with a p-doped cladding layer; an n-doped cladding layer; an active layer between the n-doped and p-doped cladding layer; and a waveguide modifying layer between the active layer and the n-doped cladding layer, an energy level of the waveguide modifying layer having a value between energy levels of the active layer and the n-doped cladding layer.

It is to be understood that both the foregoing general description and the following detailed description are merely exemplary of the invention, and are intended to provide an overview or framework for understanding the nature and character of the invention as it is claimed. The accompanying drawings are included to provide a further understanding of the invention, and are incorporated in and constitute part of this specification. The drawings illustrate various features and embodiments of the invention, and together with the description serve to explain the principles and operation of the invention.

### BRIEF DESCRIPTION OF THE DRAWINGS

The various advantages of the present invention will become apparent to one skilled in the art by reading the following specification and subjoined claims and by referencing the following drawings, in which:

FIG. 1 schematically illustrates the layered structure of a conventional laser;

FIG. 2 schematically illustrates an embodiment of a layered structure of a semiconductor laser having an asymmetric waveguide structure according to the present invention; and

FIG. 3 illustrates an L-l curve of a conventional laser compared with an L-l curve of a laser fabricated according to the present invention.

### DETAILED DESCRIPTION OF THE PREFERRED EMBODIMENTS

The following description of the preferred embodiment(s) is merely exemplary in nature and is in no way intended to limit the invention, its application, or uses.

As will become apparent from the following discussion, output power is a function of many different factors. In general, increasing the length of a semiconductor laser is one such approach to increasing output power. This approach is limited, however, by the optical loss of the laser and typically has a practical limit beyond which increased length no longer provides increased power. Thus, the present invention provides a mechanism for reducing optical loss so that the benefits of increased length can fully be realized. To this end, a waveguide modifying layer enables the reduction of the p-doped cladding layer and can also be designed to have an energy level that promotes flow of current across the semiconductor laser.

The present invention is applicable to waveguide semiconductor lasers where the optical mode is vertically confined. The invention is directed to the use of an asymmetric transverse waveguide structure to at least partially remove the optical mode from a lossy cladding layer, thus reducing the single pass loss through the laser device, and enabling operation at higher output powers. Furthermore, there is no requirement for exceeding high confinement within the active layer in order to avoid the losses of the lossy cladding layer, and so the vertical confinement requirements of the optical mode may be relaxed without increasing the losses, thus reducing the vertical divergence of the optical mode when it propagates out of the laser structure.

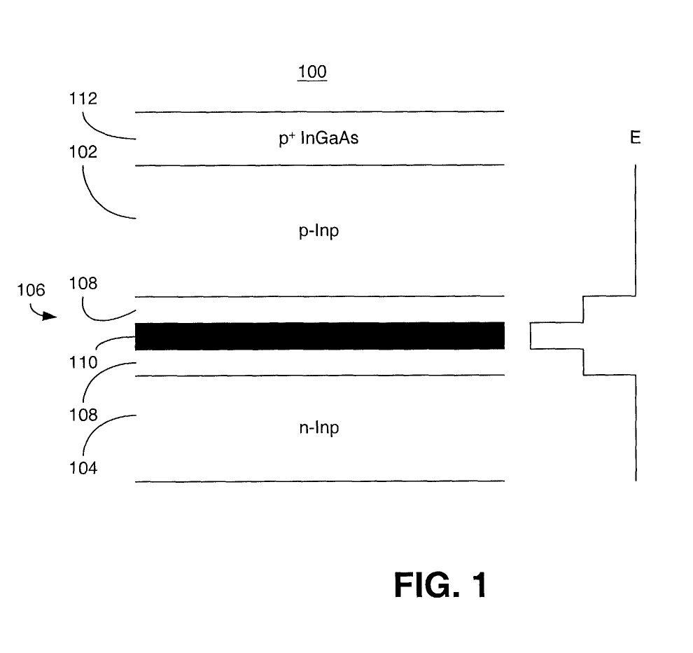

A conventional structure for a laser is illustrated in FIG. 1. The laser structure 100 has upper and lower cladding layers 102 and 104 on either side of an active layer 106. The upper cladding layer 102, in this particular embodiment, is a p-doped indium phosphide layer (p-lnP), while the cladding layer 104 is an n-doped indium phosphide layer (n-lnP). The active layer 106 in this particular embodiment includes waveguide layers 108 surrounding one or more multiple quantum well layers 110. The layers in the active layer 106 are typically formed from indium gallium arsenide phosphide (InGaAsP). The p-ln cladding layer 102 may have a highly p-doped indium gallium arsenide (p+InGaAs) contact layer 112 for contacting to a metal electrode. The relative energy level of each layer in the structure 100 is illustrated on the right side of the diagram, with the quantum well layers having the lowest energy level, and the cladding layers having the highest. In this type of structure, the optical mode is vertically symmetrical about the active layer 106.

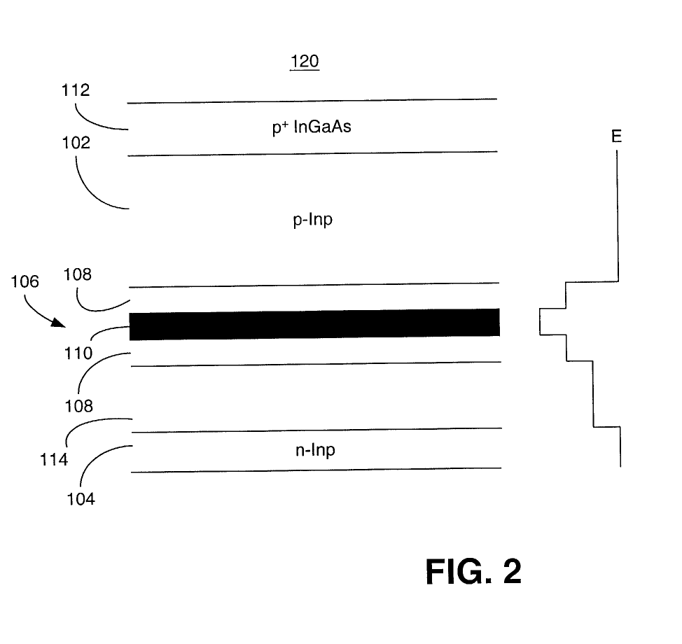

In order to reduce the overlap of the optical mode in the p-doped cladding layer 102, the present invention includes a waveguiding structure that pulls the optical mode from the p-doped cladding layer 102 towards the n-doped cladding layer 104, where the optical loss is much reduced. This is achieved by adding a high refractive index layer 114 between the lower waveguide layer 108 and the n-doped cladding layer 104, as illustrated in FIG. 2. The thickness of the waveguide modifying layer 114 depends on the refractive index of the particular material. In this particular embodiment, the waveguide modifying layer 114 is formed from InxGa₁₋ₓAs_{y}P_{1-y}, and has a refractive index higher than that of the n-doped cladding layer 104. This pulls the optical mode away from the p-doped indium phosphide layer, thus reducing the overlap of the optical mode in the lossy cladding layer 102. The energy levels of the different layers in the modified structure 120 are illustrated next to the structure. The energy level of the waveguide modifying layer 114 lies between the energy levels of the waveguiding layer 108 and the n-lnP cladding layer 104.

An additional advantage of the waveguide modifying layer 114 is that the thickness of the p-lnP cladding layer 102 may be reduced, since the optical mode is at least partially shifted out of the distance into the p-InP cladding layer 102. Reduction of the thickness of the p-doped cladding layer 102 results in a lower electrical series resistance for the device, thus reducing the laser threshold, increasing overall efficiency and reducing the heat load on the laser's cooling system.

This additional advantage contrasts with results reported by Delephine et al. “0.7W in single-mode fiber from 1.48-μm semiconductor unstable-cavity laser with low-confinement asymmetric epilayer structure”, LEOS Annual Meeting Proceedings, Nov. 10, 1999. The results reported in that paper showed that the threshold current increased by 10% and the series electrical resistance increased by 30% when an “optical trap” layer was added to the laser structure.

Semiconductor lasers using the structures illustrated in FIGS. 1 and 2 were fabricated and tested. The lasers operated at 1480 nm. The waveguide modifying layer 114 had a band gap of 1 μm, and had a thickness of 0.75 μm.

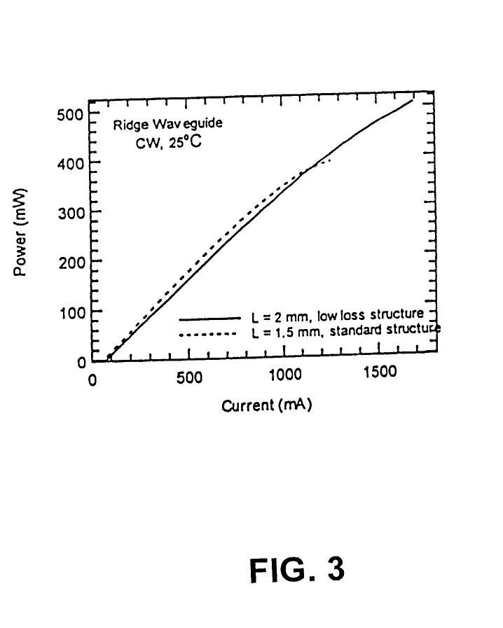

The L-l characteristics for a conventional device (dashed line) and for a laser device having a waveguide modifying layer 114 (solid line) are shown in FIG. 3. The conventional laser had a cavity length of 1.5 millimeters and produced a maximum output of approximately 400 mW at a current of 1.2 A. The laser having the modified laser structure illustrated in FIG. 2 had a cavity length of 2 millimeters, and produced an output of approximately 500 mW at a current of 1.7 Amps. Both lasers operated with ridge waveguides having a single spatial mode.

Comparison of the two L-l curves illustrates that the power of the conventional structure was beginning to roll over at approximately 1.1 A, with the result that the efficiency at any higher injection current would be drastically reduced, and that the device would suffer from excess heating. In contrast, the modified laser structure demonstrated no roll over in output power over the entire current range from 0 to 1.7 Amps. Thus the adverse effects of loss in the p-doped cladding layer were significantly reduced. The slope efficiency of the low loss structure was approximately 0.38 W/A.

Thus, an effective method of reducing the losses in the p-doped cladding layer has been demonstrated. As noted, the present invention is believed to be applicable to high power semiconductor lasers, and particularly to indium phosphide lasers used for pumping optical amplifiers in optical communications systems. It will be appreciated that various modifications may be made to the invention over the embodiments presented herein, without straying outside the scope of the invention as defined in the claims below. For example, the invention is not restricted to semiconductor lasers having p-doped indium phosphide cladding layers, and may be used for shifting the optical mode out of any cladding layer which introduces loss. Furthermore, the invention may be used with any suitable form of lateral optical confinement, for example, a ridge waveguide, a channel waveguide, a buried heterostructure, a channel waveguide, and the like.

As noted above, the present invention is believed to be applicable to high power semiconductor lasers. The invention is believed to be particularly useful for InP lasers used, for example, for pumping optical amplifiers in optical communications systems. It will be appreciated that the laser described herein is not restricted to applications for pumping fiber amplifiers, but may be used wherever a high power, high quality output light beam is required or is desirable.

Those skilled in the art can now appreciate from the foregoing description that the broad teachings of the present invention can be implemented in a variety of forms. Therefore, while this invention can be described in connection with particular examples thereof, the true scope of the invention should not be so limited since other modifications will become apparent to the skilled practitioner upon a study of the drawings, specification and following claims.

What is claimed is:

1. A semiconductor laser comprising:
a p-doped cladding layer adjacent to a first side of an active layer;
an n-doped cladding layer positioned on a second side of the active layer; and
a waveguide modifying layer disposed between the n-doped cladding layer and the active layer, the modifying layer reducing an extent by which an optical mode confined by the active layer extends into the p-doped cladding layer.

2. The laser of claim 1 wherein the modifying layer includes:
a first surface adjacent to the second side of the active layer;
a second surface adjacent to a first side of the n-doped cladding layer; and
a modifying material forming the surfaces, the modifying material having a refractive index that is higher than a refractive index of the n-doped cladding layer such that the modifying layer pulls the optical mode away from the p-doped cladding layer.

3. The laser of claim 2 wherein the modifying layer has an energy level that is between energy levels of the active layer and the n-doped cladding layer such that a series resistance of the laser is reduced.

4. The laser of claim 2 wherein the modifying layer includes indium gallium arsenide phosphide.

5. The laser of claim 2 wherein the modifying layer has a thickness in excess of 0.5 μm.

6. The laser of claim 1 wherein the p-doped cladding layer has a thickness less than 1.5 μm.

7. The laser of claim 1 wherein the p-doped cladding layer includes indium phosphide.

8. The laser of claim 1 wherein the n-doped cladding layer includes indium phosphide.

9. The laser of claim 1 wherein the active layer is in an optical waveguide.

10. The laser of claim 8 wherein the optical waveguide is buried in a planar structure.

11. The laser of claim 9 wherein the optical waveguide is a ridge waveguide.

12. A semiconductor laser waveguide modifying layer comprising:
a first surface adjacent to a second side of an active layer of the laser;
a second surface adjacent to a first side of an n-doped cladding layer of the laser; and
a modifying material forming the surfaces, the modifying material having a refractive index that is higher than a refractive index of the n-doped cladding layer such that the modifying layer pulls an optical mode away from a p-doped cladding layer of the laser.

13. The modifying layer of claim 12 further including an energy level that is between energy levels of the active layer and the n-doped cladding layer such that a series resistance of the laser is reduced.

14. The modifying layer of claim 12 further including indium gallium arsenide phosphide.

15. The modifying layer of claim 12 further including a thickness in excess of 0.5 μm.

16. A semiconductor laser comprising:
a p-doped cladding layer adjacent to a first side of an active layer, the p-doped cladding layer including indium phosphide;
an n-doped cladding layer positioned on a second side of the active layer, the n-doped cladding layer including indium phosphide;
a first surface adjacent to the second side of the active layer;
a second surface adjacent to a first side of the n-doped cladding layer; and
a modifying material forming the surfaces, the modifying material including indium gallium arsenide phosphide and having a refractive index that is higher than a refractive index of the n-doped cladding layer such that the modifying layer pulls an optical mode of the active layer away from the p-doped cladding layer.

17. The laser of claim 16 wherein the modifying layer has an energy level that is between energy levels of the active layer and the n-doped cladding layer such that a series resistance of the laser is reduced.

18. A semiconductor laser having a layered semiconductor structure, the laser comprising:
a p-doped cladding layer;
an n-doped cladding layer;
an active layer between the n-doped and p-doped cladding layers; and
a waveguide modifying layer between the active layer and the n-doped cladding layer, an energy level of the waveguide modifying layer having a value between energy levels of the active layer and the n-doped cladding layer.

19. The laser of claim 18 wherein the p-doped and n-doped cladding layers are formed from indium phosphide.

20. The laser of claim 18 wherein the active layer includes one or more quantum well layers.

21. The laser of claim 18 wherein the waveguide modifying layer is formed from indium gallium arsenide phosphide.

22. The laser of claim 18 wherein the waveguide modifying layer has a thickness in excess of 0.5 μm

23. The laser of claim 18 wherein the active layer is in an optical waveguide.

24. The laser of claim 23 wherein the waveguide is a ridge waveguide.

25. The laser of claim 23 wherein the waveguide is a waveguide buried in a planar structure.

26. The laser of claim 18 wherein the modifying layer reduces a series resistance of the laser.

27. A method for fabricating a semiconductor laser, the method comprising the steps of:
coupling a p-doped cladding layer to a first side of an active layer;
coupling a waveguide modifying layer to a second side of the active layer; and
coupling an n-doped cladding layer to the modifying layer, the n-doped cladding layer having a lower index of refraction than the modifying layer such that the modifying layer reduces an extent by which an optical mode confined by the active layer extends into the p-doped cladding layer.
